(19) United States
(12) Patent Application Publication
(10) Pub. No.: US 2009/0093114 A1
(43) Pub. Date: Apr. 9, 2009

(54) METHOD OF FORMING A DUAL-DAMASCENE STRUCTURE USING AN UNDERLAYER

(76) Inventors: Sean David Burns, Hopewell Junction, NY (US); Matthew Earl Colburn, Schenectady, NY (US); Naftali Eliahu Lustig, Croton-on-Hudson, NY (US); David R. Medeiros, Stockbridge, MA (US); Kaushal Patel, Wappingers Falls, NY (US); Libor Vyklicky, Yorktown Heights, NY (US)

Correspondence Address: SCHMEISER, OLSEN & WATTS, 22 CENTURY HILL DR., SUITE 302, LATHAM, NY, 12110, US

(21) Appl. No.: 11/869,043

(22) Filed: Oct. 9, 2007

(51) Int. Cl. H01L 21/4763

(52) U.S. Cl. 438/637; 257/E21.495

(57) ABSTRACT

A method of forming a dual-damascene wire. The method includes forming a via opening in a dielectric layer, filling the via opening with a polymeric formation including at least about 6% by weight of solids of thermal acid generator; heating the polymeric underlayer to a temperature greater than room temperature but less than about 180° C.; lithographically forming a trench in the dielectric layer and filling the via opening and the trench with an electrical conductor, a top surface of the electrical conductor substantially co-planer with the top surface of the second dielectric capping layer.

### FIELD OF THE INVENTION

The present invention relates to the field of integrated circuits; more specifically, it relates to a method of forming dual-damascene structures and to an underlayer composition for use in a lithography step in the fabrication of dual-damascene structures.

### BACKGROUND OF THE INVENTION

Photoresist poisoning presents a major challenge in the manufacturing of advanced integrated circuits during metal-wiring fabrication processing. Many semiconductor manufacturers report that the lithography process used to fabricate metal wires have exhibit deformed and missing features. Accordingly, there exists a need in the art to overcome the deficiencies and limitations described hereinabove.

### SUMMARY OF THE INVENTION

A first aspect of the present invention is a method of forming a dual-damascene wire, comprising: (a) forming an electrically conductive wire in a first dielectric layer on a substrate, a top surface of the wire substantially coplanar with a top surface of the capping layer; (b) forming a first dielectric capping layer on the top surface of the first dielectric layer and on the top surface of the wire; (c) forming a second dielectric layer on a top surface of the first dielectric capping layer; (d) forming a second dielectric capping layer on a top surface of the second dielectric layer; (e) forming a via opening extending from the top surface of the second capping layer to the top surface of the wire through the second capping layer, the second dielectric layer and the first capping layer; (f) forming from a polymeric formulation, a polymeric underlayer on the top surface of the second capping layer, the polymeric layer filling the via opening, the polymeric formation including at least about 6% by weight of solids of the thermal acid generator; (g) heating the polymeric underlayer to a temperature greater than room temperature but less than about 180° C.; (h) forming a photoresist layer over the polymeric underlayer; (i) exposing the photoresist layer to actinic radiation through a patterned photomask to form an exposed photoresist layer; (j) developing the exposed photoresist layer to form a trench opening aligned over the via opening; (k) in the trench opening, etching a trench through the second capping layer and into but not completely through the second dielectric layer; (l) removing any remaining imaging layer and polymeric underlayer; and (m) filling the via opening and the trench with an electrical conductor, a top surface of the electrical conductor substantially co-planer with the top surface of the second dielectric capping layer.

### BRIEF DESCRIPTION OF THE DRAWINGS

The features of the invention are set forth in the appended claims. The invention itself, however, will be best understood by reference to the following detailed description of an illustrative embodiment when read in conjunction with the accompanying drawings, wherein:

FIGS. 1A through 11F are cross-sectional drawings illustrating fabrication of a dual-damascene wire is according to embodiments of the present invention.

### DETAILED DESCRIPTION OF THE INVENTION

A via first dual-damascene process is one in which via openings are formed through the entire thickness of a dielectric layer followed by formation of trenches part of the way through the dielectric layer in any given cross-sectional view. All via openings are intersected by integral wire trenches above and by a wire below, but not all trenches need intersect a via opening. An electrical conductor of sufficient thickness to fill the trenches and via opening is deposited on a top surface of the dielectric and a chemical-mechanical polishing (CMP) process is performed to make the surface of the conductor in the trench co-planar with the surface the dielectric layer to form dual-damascene wires and dual-damascene wires having integral dual-damascene vias.

A lithographic process, using for example a chemically amplified photoresist formulation, includes (1) applying the photoresist layer, (2) heating the photoresist layer at a temperature greater than room temperature to drive out the casting solvent, (3) exposing the photoresist to actinic radiation through a patterned photomask to form a pattern of latent images in the photoresist layer, (4) heating the photoresist layer at a temperature greater than room temperature to increase the activity of the photo-acid generator in the exposed regions of the photoresist layer, and (5) develop away the exposed regions of the photoresist layer in a basic solution (e.g., aqueous tetramethyl ammonium hydroxide) to transfer the photomask pattern into the photoresist layer.

The term coplanar includes cases where two surfaces are substantially co-planer, that is, small variations in the surface contours of two surfaces due to variations in the chemical-mechanical-polish (CMP) rates of several materials being planarized simultaneously. An example is “dishing” where certain surface regions are depressed (e.g. concave) slightly.

The formation of via openings and wire trenches each require a separate lithographic step. It is during the second lithographic step of forming the trenches that the problem of photoresist poisoning appears.

It is believed that photoresist poisoning is caused by contaminants imbedded in the sidewalls and/or bottom of the via opening within the dielectric material and/or underlying etch stop material. These contaminants can outgas and diffuse into the photoresist during the post apply bake or post exposure bake. The contaminants may also diffuse through underlayer and bottom antireflective coatings (BARC) layers during post apply bake of each layer. If these contaminants are bases they can neutralize the acid generated during the photolysis of the photo acid generator found in the photoresist formulation. If a significant amount of acid is neutralized in the exposed region the photoresist can not undergo the acid induced de-protection reaction leading to the solubility switch necessary for development of the exposed photoresist in aqueous base. As a result features are not being formed or show severe scumming after lithography leading to diminished electrical yield due to pattern not being transferred into the dielectric in subsequent reactive ion etch (RIE) steps.

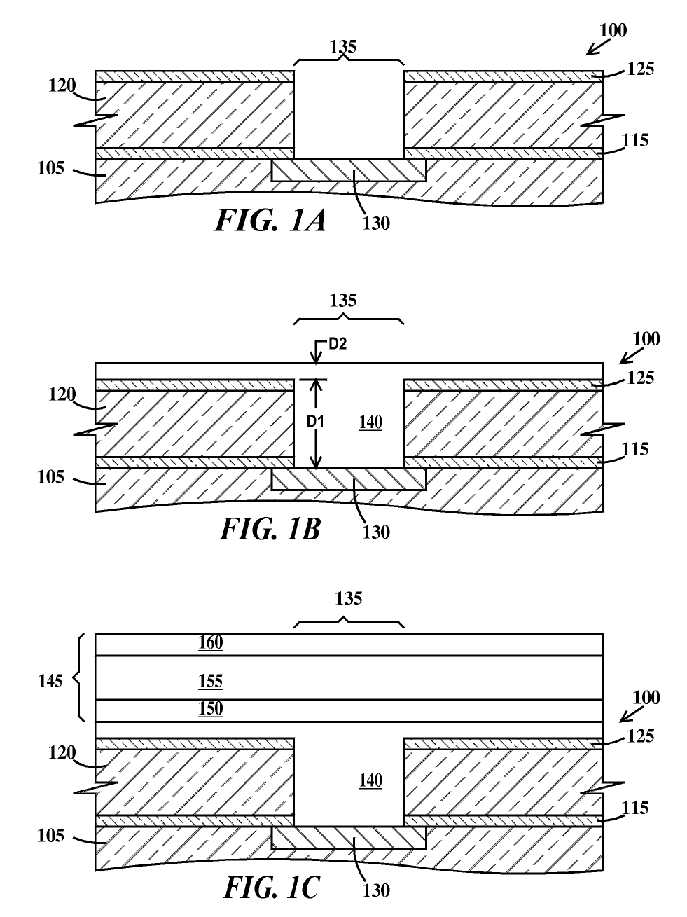

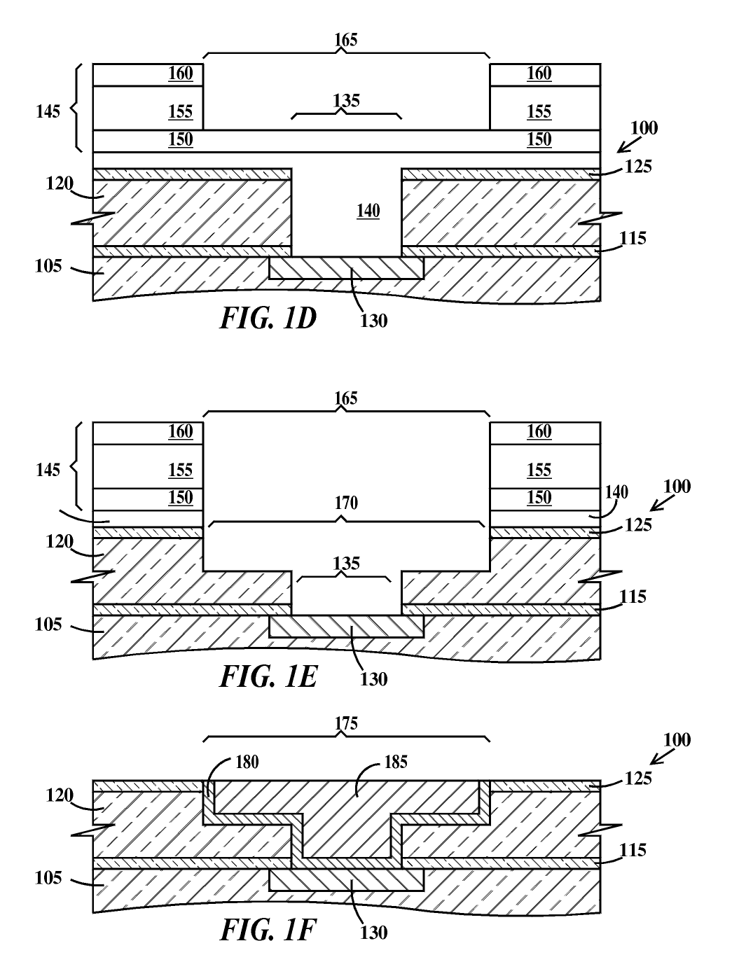

FIGS. 1A through 11F are cross-sectional drawings illustrating fabrication of a dual-damascene wire is according to embodiments of the present invention. In FIG. 1A. an integrated circuit substrate 100 includes a first dielectric layer 105, a first capping layer 115 on a top surface of the first dielectric layer, a second dielectric layer 120 on a top surface of the first capping layer, and a second capping layer 125 on a top surface of the second dielectric layer. First dielectric layer 105 includes an electrically conductive wire 130. A via opening 135 has been formed through second capping layer 125, second dielectric layer 120 and first capping layer 115 to expose a top surface of wire 130 in the bottom of the via opening. In one example, wire 130 comprises copper. In FIG. 1A, capping layer 105 extends over all edges of wire 130.

In one example, first and second dielectric layers 105 and 120 are independently a low K (dielectric constant) material, examples of which include but are not limited to hydrogen silsesquioxane polymer (HSQ), methyl silsesquioxane polymer (MSQ), SiLK™ (polyphenylene oligomer) manufactured by Dow Chemical, Midland, Tex., Black Diamond™ (methyl doped silica or SiOₓ(CH₃)_{y} or SiCₓO_{y}H_{y} or SiOCH) manufactured by Applied Materials, Santa Clara, Calif., organosilicate glass (SiCOH), and porous SiCOH. In one example, first and second dielectric layers 105 and 120 are independently between about 200 nm and about 300 nm thick. A low K dielectric material has a relative permittivity of about 2.4 or less.

In one example first and second capping layers 110 and 125 are independently silicon dioxide (SiO₂), silicon nitride (Si₃N₄), silicon carbide (SiC), silicon oxy nitride (SiON), silicon oxy carbide (SiOC), organosilicate glass (SiCOH), plasma-enhanced silicon nitride (PSiNₓ) or NBLok (SiC(N,H)). In one example first and second capping layers 110 and 125 are independently between about 5 nm and about 30 nm thick.

In FIG. 1B, a polymer underlayer 140 is formed on the top surface of second capping layer 125 and overfills via opening 135. Polymer underlayer 140 is formed by applying (e.g., by spin application) a layer of underlayer formulation (described infra) followed by heating to a temperature above room temperature to drive out the casting solvent and activate the thermal acid generator thus polymerizing the underlayer. In one example, the applied underlayer formulation is heated to no higher than 150° C. Underlayer 140 has a thickess D1 in via opening 140 and extends a thickness D2 above via opening 140 and above second capping layer 125. In one example D1 is between about 200 nm and about 300 nm and D2 is between about 20 nm and about 30 nm. Underlayer 140 is designed to neutralize volatile bases out-diffusing from the sidewalls of via opening 135 and capping layer 125 that would otherwise interfere with the photoacid generator the photoresist layer to be applied. These volatile bases include nitrogen and nitrogen/hydrogen compounds from the material of the first and second 115 and 125 capping layers and second dielectric layer 120 or residual gases from the RIE process (e.g. N₂H₂) used to etch via opening 135.

Underlayer 140 is formed from an underlayer formulation comprising a formulation of (1) a monomer, (2) one or more thermal acid generators for initiating polymerization, (3) an optional cross-linking agent, (4) an optional surfactant, (5) an optional base quencher, and (6) a casting solvent. In one example, between about 6% by weight and about 12% of the solids of the underlayer formulation comprises thermal acid generator. In one example, about 6% by weight or more of the solids of the underlayer formulation comprises thermal acid generator. In one example, about 12% by weight or more of the solids of the underlayer formulation comprises thermal acid generator. In one example, the thermal acid generator of the underlayer generates acid when heated to a temperature of about 150° C. or less. The lower the temperature at which the thermal photo acid activates, the less volatile base will out-diffuse from via opening 135 and second capping layer 125.

Using an underlayer formulation having between about 6% by weight and about 12% thermal acid generator has resulted in significant decreases in lithography defects (e.g., scumming and missing patterns) in dual-damascene processes as compared to formulations containing less than 2% by weight of solids thermal acid generator. Using an underlayer formulation with a thermal acid generator that generates acid when heated to between about 120° C. and about 180° C. has resulted in significant decreases in lithography defects (e.g., scumming and missing patterns) in dual-damascene processes over formulation containing thermal acid generators requiring heating to over 180° C. and as much as 250° C.

In one example, about 7% by weight to about 10% by weight of the solids of the underlayer formulation comprises polymer. In one example, about 1% by weight or less of the solids of the underlayer formulation comprises cross-linking agent. In one example, from about 80% by weight to about 86% by weight of the underlayer formulation is casting solvent.

Examples of suitable thermal acid generators include CDX-2507 and TAG-2181 from King Industries of Norwalk, Conn., USA., which are both esters of Dodecylbenzenesulfonic acid of the structure:

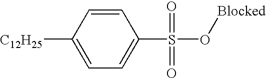

Another example is TAG-2678 from King Industries, a quaternary ammonium salt of triflic acid of the structure:

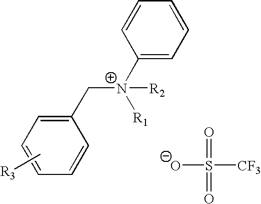

Yet another example is bis-t-butyl-phenyliodonium perfluorobutanesulfonate:

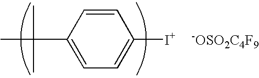

Additional suitable thermal acid generators can be found from the classes general fluorinated sulfonic acids of the general formula:

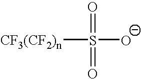

where n=0−3 and acids of the ionized species SbF₆⁻.

Examples of suitable monomers include polyhroxystyrene and novolac based monomers. Many other monomer compositions known in the art are suitable, for example those described in U.S. Pat. No. 6,924,339, and U.S. Pat. No. 7,226,721 B2, which are hereby incorporated by reference. An exemplary base quencher is tetrabutylammonium hydroxide. An exemplary casting solvent is about 70% by weight propylene glycol methyl ether acetate (PGMEA) and 30% by weight cyclcohexanone.

The underlayer formulation is applied (e.g., by spin application) and heated to a temperature above room temperature. In one example, the underlayer bake temperature is between about 120° C. and about 180° C. In one example, the underlayer bake temperature is higher room temperature but no higher than about 150° C. In one example, the underlayer bake temperature is higher room temperature but no higher than about 170° C.

In FIG. 1C, an imaging layer 145 is applied on top of underlayer 140. Imaging layer 145 includes an optional BARC 150, a photoresist layer 155, and an optional top antireflective coating (TARC) 160. Additionally a topcoat may be applied on top of TARC 160 or instead of TARC 160. Topcoats are typically used in (e.g., water) immersion lithography. It should be understood that various combinations of TARC, BARC and topcoat may be used with photoresist layer 155, including no TARC, BARC or topcoat. As each layer of imaging layer 145 is applied (e.g., by spin application) a bake by heating above room temperature is performed before application of the next layer, though some intermediate bakes may be eliminated.

In FIG. 1D, imagining layer 145 is exposed to actinic radiation through a photomask, optionally heated above room temperature, and then developed to form opening 165 in TARC 160 and photoresist layer 155.

In FIG. 1E, an RIE is performed to etch a trench 170 into second capping layer 170 and into but not through second dielectric layer 120. BARC 150 and underlayer 140 are also removed by the RIE where not protected by photoresist layer 155. Trench 170 intersects via opening 135. Trench 170 overlaps all edges of via opening 135.

In FIG. 1F, any remaining imaging layer 145 and underlayer 140 (see FIG. 1E) are removed and an electrically conductive dual-damascene wire 175 formed in trench 165 and opening 135 (see FIG. 1E). Wire 175 includes a liner 180 and a copper core conductor 185. In one example liner 180 is formed by depositing a conformal layer of tantalum nitride (TaN), followed by depositing a conformal layer of tantalum (Ta), followed by depositing a seed layer of copper (Cu). Next core conductor 185 is formed by electroplating copper, followed by a CMP, so a top surface of wire 175 is substantially co-planer with the top surface of second capping layer 125.

Thus the embodiments of the present invention provide a method of fabricating a dual-damascene wire structure less prone to lithographically induced defects and an improved underlayer composition for use in forming dual-damascene wire structures.

The description of the embodiments of the present invention is given above for the understanding of the present invention. It will be understood that the invention is not limited to the particular embodiments described herein, but is capable of various modifications, rearrangements and substitutions as will now become apparent to those skilled in the art without departing from the scope of the invention. Therefore, it is intended that the following claims cover all such modifications and changes as fall within the true spirit and scope of the invention.

1. A method of forming a dual-damascene wire, comprising:
(a) forming an electrically conductive wire in a first dielectric layer on a substrate, a top surface of said wire substantially coplanar with a top surface of said capping layer;
(b) forming a first dielectric capping layer on said top surface of said first dielectric layer and on said top surface of said wire;
(c) forming a second dielectric layer on a top surface of said first dielectric capping layer;
(d) forming a second dielectric capping layer on a top surface of said second dielectric layer;
after (d), (e) forming a via opening extending from said top surface of said second capping layer to said top surface of said wire through said second capping layer, said second dielectric layer and said first capping layer, a region of said top surface of said wire exposed in a bottom of said via;
after (e), (f) forming, from a polymeric formulation, a polymeric underlayer on said top surface of said second capping layer, said polymeric layer filling said via opening and contacting said region of said top surface of said wire, said polymeric formation including at least about 6% by weight of solids of a thermal acid generator;
(g) heating said polymeric underlayer to a temperature greater than room temperature but less than about 180° C.;
(h) forming a photoresist layer over said polymeric underlayer;
(i) exposing said photoresist layer to actinic radiation through a patterned photomask to form an exposed photoresist layer;
(j) developing said exposed photoresist layer to form a trench opening aligned over said via opening;
(k) in said trench opening, etching a trench through said second capping layer and into but not completely through said second dielectric layer;
(l) removing any remaining imaging layer and polymeric underlayer; and
(m) filling said via opening and said trench with an electrical conductor, a top surface of said electrical conductor substantially co-planer with said top surface of said second dielectric capping layer.

2. The method of claim 1, wherein said underlayer formulation comprises:
a monomer;
said thermal acid generator; and
a casting solvent.

3. The method of claim 2, wherein said monomer is selected from the group consisting of polyhydroystyrene monomers and novolac monomers.

4. The method of claim 2, wherein said thermal acid generator is selected from the group consisting of

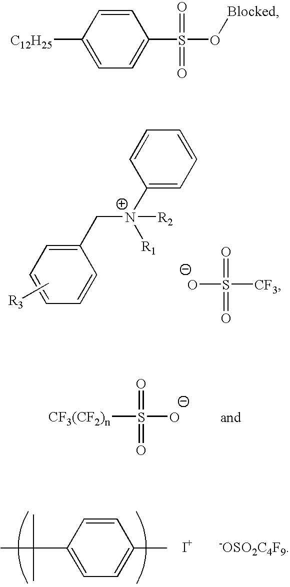

5. The method of claim 2, wherein said thermal acid generator generates acid when heated to a temperature greater than room temperature but less than about 170° C.

6. The method of claim 2, wherein said thermal acid generator generates acid when heated to a temperature greater than room temperature but less than about 150° C.

7. The method of claim 2, wherein said polymeric formulation further includes a base quencher.

8. The method of claim 7, wherein said base quencher is tetrabutlyammonium hydroxide.

9. The method of claim 1, further including:
between (g) and (h), forming a bottom antireflective coating on said top surface of said polymeric underlayer; and
step (h) includes forming said photoresist layer on a top surface of said bottom antireflective coating.

10. The method of claim 1, further including:
between (h) and (i), forming a top anti-reflective coating on a top surface of said photoresist layer.

11. The method of claim 1, further including:
between (i) and (j), heating said photoresist layer to a temperature greater than room temperature.

12. The method of claim 1, wherein a width of said via opening measured in a direction parallel to said top surface of said second dielectric capping layer is less than a width of said trench measured in said direction.

13. The method of claim 1, wherein step (m) includes:
depositing a tantalum nitride layer on all surfaces of said via opening, on all surfaces of said trench, on said top surface of said second dielectric capping layer and on said top surface of said wire exposed in said bottom of said trench;
depositing a tantalum layer on said tantalum nitride layer;
depositing a copper layer on said tantalum layer;
electroplating copper on said copper layer;
performing a chemical-mechanical-polish to form said dual-damascene wire, a top surface of dual-damascene wire substantially co-planer with the top surface of second dielectric capping layer.
